(19) United States
(12) Patent Application Publication
(10) Pub. No.: US 2002/0066936 A1
(43) Pub. Date: Jun. 6, 2002

(54) Electronic and optoelectronic devices using fractional carriers

(75) Inventor: Humphrey J. Maris, Barrington, RI (US)

Correspondence Address: Harry F. Smith, Esq., OHLANDT, GREELEY, RUGGIERO & PERLE, L.L.P., 10th Floor, One Landmark Square, Stamford, CT, 06901, US

(73) Assignee: Brown University Research Foundation, Providence, RI (US)

(21) Appl. No.: 09/871,327

(22) Filed: May 31, 2001

Related U.S. Application Data
(60) Provisional application No. 60/209,100, filed on Jun. 2, 2000.
(60) Provisional application No. 60/209,656, filed on Jun. 5, 2000.

(51) Int. Cl. H01L 29/06

(52) U.S. Cl. 257/431

(57) ABSTRACT

An electronic or optoelectronic device includes a generation unit and an active unit (which may be part of a passive or active device). The generation and active units provide different functions in the device, but may physically occupy the same space. The generation unit includes an energy element and a material with a region of a selected energy distribution including a particle arranged in the region of the selected energy distribution. The energy element is constructed and arranged to provide energy to the region to create fractional carriers from the particle. The active unit is arranged to receive the created fractional carriers and manipulate the fractional carriers to provide a functional output.

### CROSS-REFERENCE TO RELATED APPLICATIONS

The present application is claiming priority of U.S. Provisional Patent Application Ser. Nos. 60/209,100, which was filed on Jun. 2, 2000, and 60/209,656, which was filed on Jun. 5, 2000.

This invention was made with government support from the National Science Foundation through grants DMR 97-03529 and INT-9314295. The U.S. government has certain rights in the invention.

### FIELD OF THE INVENTION

The present invention relates to creating fractional particles (fractional carriers) from elementary particles and also relates to electronic and optoelectronic devices that use the created fractional carriers.

### BACKGROUND OF THE INVENTION

Charge carriers play a central role in electronic and optoelectronic devices. Vacuum tubes and other similar devices utilize free electrons, which have a negative charge (−1e). Transistors are made of semiconductor materials in which the electric current is carried by electrons and by holes. Holes are analogous entities to electrons and have a positive charge. These two types of charge carriers (together with the structure of semiconductor materials including local potential and other) define the electronic behavior of transistors, diodes and other semiconductor devices.

The electrical and optical properties of semiconductor materials can be varied over a wide range by adding small quantities of various elements (that is, by doping), which changes the concentration of charge carriers. In addition to single element semiconductor materials (for example, Si or Ge) many different types of compound materials (for example, GaAs or In P) are used for electronic or optoelectronic devices. By making compositional changes on an atomic scale, the electrical and optical properties of semiconductor materials can be continuously or abruptly altered. For example, by changing the chemical structure of a semiconductor material, quantum wells, quantum wires and quantum dots can be fabricated. See, for example, “Quantum Semiconductor Structures,” by Claude Weisbuch and Borge Vinger, published by Academic Press, 1991, which is incorporated by reference.

Optoelectronic devices utilize both electric and optical properties of various materials. These devices utilize electrons or holes interacting with photons (which are units of light) and phonons (which are units of thermal vibrations). Optoelectronic devices are used for sensing, optical communication, optical computation and in other applications. These devices usually include active or passive electronic elements closely integrated with and coupled to optical elements.

Superconducting devices use another type of carriers called Cooper pairs. When a superconductor material is cooled below the transition temperature (i.e., the critical temperature) it achieves the superconducting state, where electrons are grouped in pairs, i.e., Cooper pairs. Cooper pairs move in the superconducting system as a single entity. If an electrical voltage is applied to the superconductor, all Cooper pairs start moving and form an electric current. When the voltage is removed, this current continues to flow indefinitely because Cooper pairs encounter no resistance. However, as a superconductor is warmed up above the transition temperature, the Cooper pairs separate into individual electrons and the material becomes normal, i.e., non-superconducting.

Superconducting devices are presently employed in areas that require low noise, high sensitivity and other unique characteristics arising from the unique nature of the superconducting state. Active superconducting devices are used as low-noise, high-frequency mixers. Passive superconducting devices are used as resonators and filters, superconducting phase shifters, local oscillators and mixers. Integrating superconducting systems may be fabricated to use several superconducting quantum interference devices (SQUIDs), Josephson arrays, microwave detectors, digital signal processors and computers. SQUID systems are designed to measure directly magnetic flux and Josephson devices utilize electrical characteristics of Josephson junctions in performing various electronic functions.

In general, the development of electronic and optoelectronic devices shows that there are needs and opportunities for improvement of existing devices and for new devices that utilize new types of carriers.

### SUMMARY OF THE INVENTION

These teachings relate to creating fractional particles (fractional carriers) from elementary particles, and also relate to electronic and optoelectronic devices that use the created fractional carriers.

According to one aspect, in an electronic or optoelectronic device, a method of using fractional carriers includes the acts of providing a region of a selected energy distribution in a selected material that has a particle, arranging the particle in the region of the selected energy distribution, supplying energy to the region to create fractional carriers from the particle, and using the created fractional carriers in the electronic or optoelectronic device.

According to another aspect, an electronic or optoelectronic device includes a generation unit and an active unit (which may be part of a passive or active device). The generation and active units provide different functions in the device, but may physically occupy the same space. The generation unit includes an energy element and a material with a region of a selected energy distribution including a particle arranged in the region of the selected energy distribution. The energy element is constructed and arranged to provide energy to the region to create fractional carriers from the particle. The active unit is arranged to receive the created fractional carriers and manipulate the fractional carriers to provide a functional output.

Preferred embodiments of these aspects include one or more of the following features. The particles may be electrons. The energy element may include an internal or an external energy source. The energy element may include a gate, an electrode, a grid, an optical port, a radiation antenna, a magnet, a heating element, or another element. The energy element may provide one or more of the following: electric field, magnetic field, optical radiation, ionizing radiation, thermal energy, injection of particles or ions.

The active unit of the electronic or optoelectronic device may facilitate interaction of the fractional carriers with photons, phonons, rotons, electrons, holes, Cooper pairs, ions, atoms, or their combination. The active unit may include a detector and the functional output corresponds to a detected signal. The detector provides the detected signal reflecting electromagnetic radiation received at the detector. Alternatively, the active unit may include a switch and the functional output corresponds to a selected state, or the active unit includes an amplifier and the functional output provides amplified input signal. Alternatively, the active unit may include a filter and the functional output corresponds to a modified input signal, or the active unit may include a phase shifter or splitter.

A farther aspect of these teachings provides a technique for encoding, storing and reading out information. A method encodes information and stores the encoded information by trapping a portion of a wave function within a spatial region. The spatial region may be located within a body or layer of semiconductor material, and the spatial region includes at least one of a quantum well, a quantum wire or a quantum dot. The process of storing the encoded information includes changing a voltage potential within the semiconductor material at a minimum predetermined rate.

### BRIEF DESCRIPTION OF THE DRAWINGS

FIGS. 1 and 1A show schematically devices for producing fractional particles used as carriers in electronic or optoelectronic devices.

FIG. 2 shows schematically a semiconductor device for production of electrinos used as carriers in electronic or optoelectronic devices.

FIGS. 3 and 3A show diagrammatically another device for production of electrinos in superfluid helium.

FIGS. 4A through 4E show different shapes of bubbles containing electrons in different quantum states at zero liquid pressure.

FIGS. 5A through 5C show different shapes of electron bubbles at the 1p energy state and pressures of 0, 10, and 20 bars, respectively.

FIG. 6A is a graph of the 1s, 1p and 2p energy states as a function of pressure.

FIG. 6B is a graph of the 1s→1p and 1s→2p energy transitions for the electron states as a function of pressure.

FIGS. 7A, 7B, 7C and 7D illustrate a double well model. FIGS. 7A and 7B illustrate the potential and the wave function, respectively, for a particle that has an equal probability of being found in either well. FIG. 7C illustrates an example where the left hand potential well is made narrower then the right hand potential well, and FIG. 7D illustrates the corresponding probabilities of finding the particle in either well.

FIG. 8 is a contour plot of the energy of a bubble containing a 1p electron as a function of parameters a₀ and a₂. In FIG. 8, along the line on which a₂=2 a₀, the waist (shown also in FIG. 5C) of the electron bubble has a zero radius and thus the bubble has split into two electrino bubbles.

FIG. 8A illustrates the geometry of the model used to study the stability of the fission process that creates two electrino bubbles.

FIGS. 8B and 8C are contour plots of the energy as a function of the radii R₁ and R₂ when an electron bubble is in the excited state and in the ground state, respectively.

FIG. 9 is a graph of energy of the 1s→1p transition for an e^{½} electrino bubble as a function of pressure.

FIG. 10 is a graph of potential energy of interaction between two e^{½} electrino bubbles as a function of the distance between the centers of the bubbles.

### DETAILED DESCRIPTION OF THE PREFERRED EMBODIMENTS

These teachings will be first described in the context of experiments conducted using superfluid helium, and further applications of these teachings will then be described in the context of semiconductor devices.

In the following description a reference to an “energy region” implies a region wherein the potential energy of an electron has a certain value, and a reference to an “energy increase” implies increasing the potential energy within such a region, for example, by applying or changing a voltage.

It is also noted that in the following description reference is made to fractional electrons or particles or carriers, also referred to for convenience as “electrinos”. However, it should be kept in mind that these terms are being used to denote parts of a wave function that are confined to separated regions, and that the fractional parts of the wave function may or may not have a physical manifestation that can be identified as particulate in nature.

In general, and by way of introduction, when a wave packet of an elementary particle is incident on a potential barrier, one part of the wave packet is transmitted, and another part is reflected. To determine the location of the particle, according to the conventional interpretation of quantum theory, the probability that the particle will be found on the right hand side of the barrier is as follows:

$${P}_{R} = {\int }_{RHS} {\vert ψ \vert}^{2} ⅆ V , \qquad ( 1 )$$

where the integral is over all of space on the right hand side of the barrier.

Let ψ_{L} and ψ_{R} be the lowest energy solutions of Schrodinger's equation for two energy regions of a volume. An energy element provides external energy for raising the barrier height of a barrier region to make the amplitude for quantum tunneling through the barrier very small. When the barrier region is increased the particle is confined in one energy region. The resulting energies corresponding to these solutions are E_{L} and E_{R}, respectively. The particle will exert the following pressure P on an end wall:

$$P = \frac{ℏ}{2 m} {\vert ∇ ψ \vert}^{2} , \qquad ( 2 )$$

where ∇ψ is the gradient of the wave function at the wall, and m is the mass of the particle.

When the barrier region has low potential, the particle in the ground state spreads over both energy regions with equal probability. If the barrier height of barrier region is rapidly increased, the system will not remain in the ground state, and the wave function of the electron will be nonzero in both energy regions (i.e., the wave function will be nonzero in both the left and right regions). That is, the rapid change in the barrier height traps a part of the wave function of the particle in each of the two energy regions.

FIG. 3 and 3A show schematically a device 60, which includes a generation unit 60A and an active unit 60B. Generation unit 60A is constructed and arranged to produce fractional particles, such as electrinos, in superfluid helium. Device 60 includes a refrigerator 62 for cooling liquid helium below 2.17 K, a light source 64 emitting a beam 66, and a electron source 68. Light source 64 provides light of energies in the range of 0.1 eV to 1.0 eV.

Refrigerator 62 cools liquid helium down to a temperature below 2.17 K. (Helium has two naturally occurring isotopes, i.e., ⁴He and ³He, wherein the abundance of ⁴He to ³He is about 10⁶ to 1. Thus, I consider in this description only ⁴He). The boiling point of ⁴He is 4.2 K (at one atmosphere of pressure) and ⁴He remains liquid all the way to T=0 K. Above 2.17 K (a phase transition point called the λ point) liquid helium is in a normal state (He I), and below 2.172 K liquid helium is in a superfluid state (He II) where it assumes a set of unique properties. Superfluid ⁴He loses viscosity and assumes a highly ordered state, wherein the He atoms are in the ground state (having lowest or zero-point energy). Superfluid ⁴He can be modeled using a well known two component theory, under which the superfluid component increases as the temperature decreases.

When an electron is inserted into He II, a helium atom attracts the electron at large distances, but repels it at short distances due to the Pauli principle. Because the interatomic forces in He are weak, an electron injected into helium forms a structure referred to as an electron bubble. That is, the injected electron in the liquid resides in a cavity from which essentially all helium atoms are excluded.

Generation unit 60A of device 60 generates fractional electrons (electrinos) by exciting the electron bubbles created in He II. Active unit 60B then utilizes the fractional electrons and provides a functional output. In the following description, the creation of novel electrino bubbles is explained in detail. As a first approximation, the energy of the electron bubble can be taken as the sum of the energy Eₑₗ of the electron, the surface energy of the bubble, and the energy of creating the bubble volume. Thus,

E=Eₑₗ+α∫dA+P∫dV, (3)

where α is the surface energy of helium per unit area, P is the applied pressure, and the integrals are over the surface and volume of the bubble. If the penetration of the electron wave function into the helium is neglected, for an electron in the 1s state, Eq. 3 becomes

$$E = \frac{{h}^{2}}{8 {mR}^{2}} + 4 π {R}^{2} α + \frac{4}{3} π {R}^{3} P , \qquad ( 4 )$$

where m is the mass of the electron, and R is the radius of the bubble. If the pressure is zero, the lowest energy is obtained with a radius of

$${R}_{0} = {( \frac{{h}^{2}}{32 π m α} )}^{1 / 4} \qquad ( 5 )$$

This is the radius of a spherical bubble containing an electron in the ground state. One can also find the equilibrium shape and size of a bubble containing an electron in an excited state.

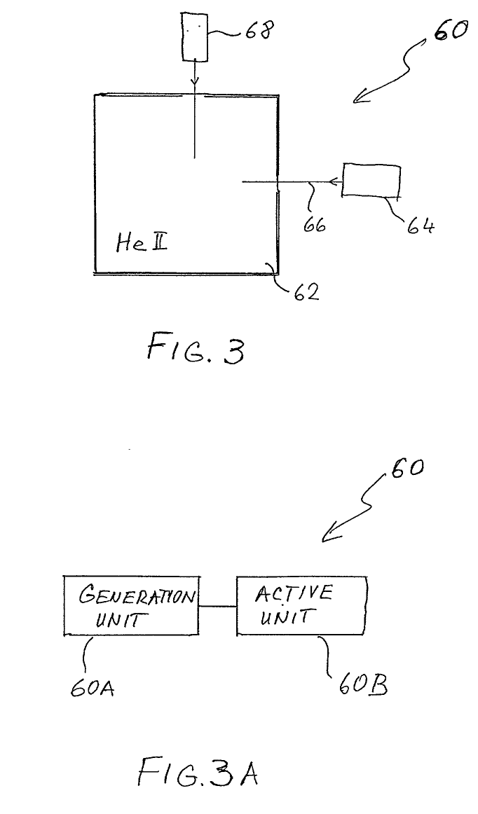

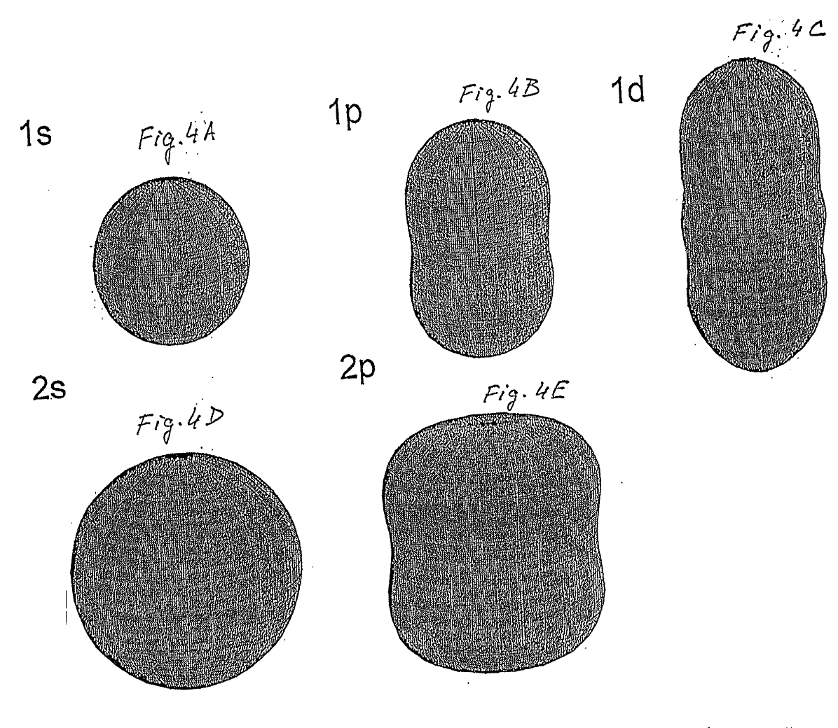

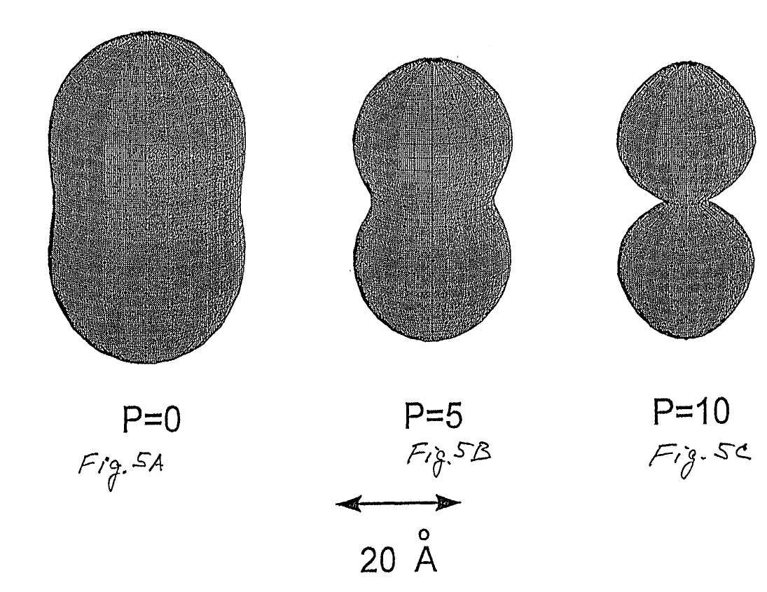

FIGS. 4A through 4E show the equilibrium shapes for the electron bubble at several excited states for zero pressure. The radius R₀ of the electron bubble calculated from Eq. 5 for T=0 K, and with zero applied pressure, is 19.4 \acute{Å}. The radius of the bubble is significantly larger than the interatomic spacing, but the width of the liquid-vapor interface is 7 \acute{Å}, which is not entirely negligible compared to the bubble radius. It is possible to use a density functional method to make an approximate correction for the finite thickness of the bubble wall (See J. Classen, C.-K. Su, M. Mohazzab and H. J. Maris, Phys. Rev. Vol. 57, p. 3000 (1998) which is incorporated by reference). At finite temperatures the electron bubble will contain some helium vapor. The effect of vapor inside the bubble becomes important at temperatures above about 3 K. If device 60 operates at temperatures below 1.5 K, the effect of helium vapor becomes unimportant.

To calculate the properties of the electron bubble in an excited state, I used a simplified approach according to Grimes and Adams (Phys. Rev. B Vol. 41, p. 6366 (1990)) and some further simplifications described below. Grimes and Adams showed that the experimentally-measured photon energies E₁ₛ₋₁ₚ and E₁ₛ₋₂ₚ for transitions from the ground 1s state to the 1p and 2p states, respectively, were in good agreement with results calculated for a simplified model. They took the surface energy α to have a constant value of 0.341 erg cm⁻², independent of pressure, and used the Wigner-Seitz approximation to estimate the pressure dependence of V₀. (Grimes and Adams take the value of V₀ at zero pressure to be 1.02 eV.)

I also made the following simplifications of the model of Grimes and Adams. In all of the calculations, I neglected the polarization energy due to helium atoms. This polarization energy makes a small contribution to the total energy of the bubble, and is difficult to treat correctly for bubbles with electrons in excited states. To calculate the polarization energy it is essential to make allowance for the quantum fluctuations in position of the electron inside the bubble. When this contribution to the energy is neglected, the Grimes and Adams model still gives very good agreement with the experimental data for E₁ₛ₋₁ₚ and E₁ₛ₋₂ₚ. I also neglected the effect of the penetration of the wave function into the helium liquid.

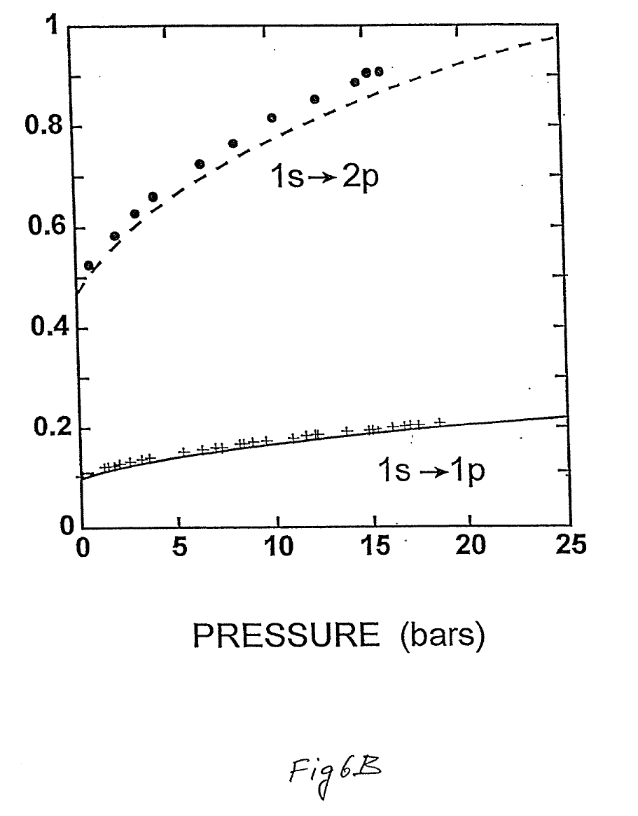

FIG. 6A shows the dependence of the 1s, 1p and 2p energy states on pressure. For all of these states the radius of the bubble is equal to the equilibrium radius of the is bubble. The total energy of the bubble is plotted, including the surface and volume terms. For each pressure the bubble has an equilibrium radius R₁ₛ(P) that minimizes the total energy when the electron is in the 1s state. Also included in FIG. 6A are the energies \tilde{E}₁ₚ and \tilde{E}₂ₚ of spherical bubbles of the same radius, but with the electron in the higher energy states 1p and 2p, respectively. (The tilde is to denote that these energies do not correspond to states in which the bubble is in mechanical equilibrium, i.e., the size and shape of the bubble has not been adjusted to minimize the total energy.) Furthermore, the energies shown in FIG. 6A are calculated for an electron moving in a spherical bubble with a potential V₀ outside the bubble. That is, in these calculations allowance is made for the penetration of the wave function into the helium. The radius for the 1s bubble at zero pressure is found to be 17.9 \acute{Å}; this value is only slightly smaller than 19.4 \acute{Å} found when the penetration of the wave function into the helium is neglected.

Device 60 includes light source 64, which provides optical energy for the system. According to the Franck-Condon principle, when the electron is in the ground state, optical absorption can occur at the following photon energies E₁ₛ₋₁ₚ=\tilde{E}₁ₚ-E₁ₛ and E₁ₛ₋₂ₚ=\tilde{E}₂ₚ-E₁ₛ. These photon energies are plotted in FIG. 6B, which includes the data of Grimes and Adams (published in Phys. Rev. B Vol. 41, p. 6366 (1990) and Phys. Rev. B Vol. 45, p. 2305 (1992)) for the 1s→1p transition, and Zipfel and Sanders for the 1s→2p transition (published in Proceedings of the 11th International Conference on Low Temperature Physics, edited by J. F. Allen, D. M. Finlayson, and D. M. McCall (St. Andrews University, St. Andrews, Scotland, 1969), p. 296; and C. L. Zipfel, Ph.D. thesis, 1969 University of Michigan library) FIG. 6B shows a good agreement between the calculation and the data. For the 1s→1p transition, light source 64 provides light of energies in the range of 0.1 eV to 0.2 eV, and for the 1s→2p transition light, source 64 provides light of energies in the range of 0.45 eV to 1.0 eV.

The equilibrium shapes for the excited states of electron bubbles can be calculated as follows: A shape for the helium bubble was assumed. The Schrodinger equation for the electron was then solved with a potential energy that is zero inside the bubble and V₀ outside. For a given set of quantum numbers for the electron state, the shape of the bubble was then varied so as to minimize the total energy. The total energy E is given by Eq. 3. The shape and total energy of bubbles containing an electron in an excited state have been calculated previously by Duvall and Celli (published in Phys. Lett. Vol. 26A, p. 524 (1968), and Phys. Rev. Vol. 180, p. 276 (1969)). Duvall and Celli used a perturbation approach in which the distortion of the shape from spherical was treated as a small parameter. The energy of some of these states has also been estimated by Fowler and Dexter (published in Phys. Rev. Vol. 176, p. 337 (1968)), who used a simplified model in which the bubble shape was taken to be a rectangular box.

In the following, for simplicity, only bubble shapes that have axial symmetry have been considered. Thus the wave function of the electron inside the bubble will have a definite azimuthal quantum number m, and can be written as follows:

$$ψ ( r , θ , φ ) = {\sum }_{l} {A}_{l} {P}_{l}^{m} ( cos θ ) {ⅇ}^{ⅈ m φ} {j}_{l} ( kr ) , \qquad ( 6 )$$

Where {Aₗ} are coefficients to be determined, Pₗ^{m}(cosθ) are associated Legendre polynomials, jₗ (kr) is a spherical Bessel function, and k=(2mEₑₗ)^{½}/h. As a first step, I calculated the electron energy in the limit V₀→∞ so that ψ is zero at the bubble wall. I made an initial guess for the energy Eₑₗ. The sum over I extends up to some maximum value lₘₐₓ. To look for a state of even parity, the coefficient A₀ is set equal to unity, and all {Aₗ} for odd I are set equal to zero. Then, the remaining coefficients are adjusted so as to minimize the following integral:

S≡∫∫¦ψ(r,θ,φ)¦²d cosθdφ (7)

This integral is over the surface of the bubble. This minimization procedure leads to a set of linear equations for the {Aₗ} coefficients. Let the value of S after the {Aₗ} have been chosen in this way be Sₘᵢₙ. Then the energy Eₑₗ is adjusted to find values at which Sₘᵢₙ becomes close to zero. Since for these energies Schrodinger's equation is satisfied inside the bubble and also ψ is very small on the surface of the bubble, these values of Eₑₗ must be the energy eigenvalues. The eigenfunction can then be calculated from the {Aₗ} coefficients. To find states of odd parity the same procedure is used except all the even I coefficients are set zero, and {Aₗ} is set equal to unity. If Iₘₐₓ is chosen to sufficiently large, the results for Eₑₗ are independent of Iₘₐₓ.

For each excited state there will be a shape of the electron bubble that corresponds to a minimum energy, which I call the equilibrium shape. To find this shape I looked for a minimum in the total energy as described above. I used the following to find the shape that minimizes the energy:

\tilde{R}(θ)=Σα_{L}P_{L}(cosθ), (8)

where \tilde{R}(θ) is the distance from the origin to the bubble surface in the direction θ, P_{L}(cosθ) are Legendre polynomials, and {a_{L}} are some coefficients. The summation is over even values of L from zero to a maximum value Lₘₐₓ. Note that only shapes with axial symmetry are considered. The set of {a_{L}}coefficients are then varied to obtain the minimum energy.

FIGS. 4B through 4E shows the equilibrium shapes of several excited states for zero pressure. These results were obtained with Lₘₐₓ=6; the use of a larger value does not change the shapes significantly. The eigenvalues obtained in this way do not allow for the penetration of the wave function into the barrier. As a test, I calculated the energies \tilde{E}₁ₛ₋₁ₚ and \tilde{E}₁ₛ₋₂ₚ for P=0 when ψ is required to go to zero at the bubble wall, and also when the wave function penetrates into the helium. I found that when there is no penetration, \tilde{E}₁ₛ₋₁ₚ and \tilde{E}₁ₛ₋₂ₚ are increased by only 5 and 7%, respectively, compared to the values found for these quantities when penetration is taken into account.

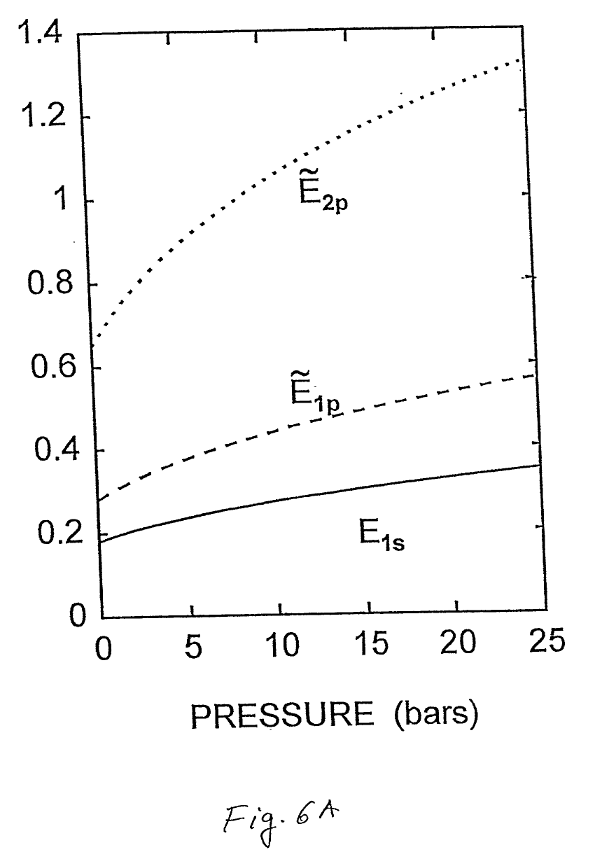

Referring to FIGS. 4A through 4E, the bubble shapes can be understood qualitatively in terms of the balance between the pressure exerted on the bubble wall by the electron, the surface tension, and by the liquid pressure. The pressure exerted by the electron is given by Eq. 2. For the 1p state, for example, the electron pressure vanishes in the plane z=0, and the bubble has a slight waist coinciding with the xy plane. As the pressure is increased, the size of the bubble decreases, and the waist becomes more pronounced, as shown in FIGS. 5A through 5C.

FIGS. 5A through 5C show the shape of the bubble with the electron in the 1p state at pressures of 0, 5 and 10 bars, respectively. At pressures of 10 bars and above, the waist of the bubble has a radius of only a few Angstroms. As shown in FIGS. 5A through 5C, at high pressures, the bubble shape closely approximates two spheres having an equal radius (R₂) and overlapping by a small amount. The wave function inside each sphere is a 1s wave function with origin at the center of the sphere. The wave functions in the two spheres have opposite signs. In this pressure range, where the waist radius is small, the numerical method for solving Schrodinger's equation becomes inaccurate unless a very large value of Lₘₐₓ is used.

I can consider that each sphere has an energy as follows:

$${E}_{1 / 2} = \frac{1}{2} \frac{{h}^{2}}{8 {mR}_{2}^{2}} + 4 π {R}_{2}^{2} α + \frac{4}{3} π {R}_{2}^{3} P , \qquad ( 9 )$$

This formula is identical to the expression for the energy of a bubble containing a is state electron (Eq. 4), apart from the factor of ½ that arises because each of the spheres contains only one half of the electron wave function. I have confirmed that the energy (E) found by the numerical solution is close to the value 2E_{½}.

When the radius of the waist approaches atomic dimensions, the precise shape of the equilibrium 1p state at high pressures can be determined only by constructing a more elaborate model. One approach would be to use a density functional model for the helium.

I consider now the dynamics of the optical absorption process. As described above, light source 64 can optically excite an electron from the ground state into one of the higher states, such as the 1p. The time scale for electron motion is of the order of

$$\frac{{mR}^{2}}{h} ,$$

where R is the radius of the bubble. The corresponding time is of the order of 10⁻¹⁴s. The time scale for the motion of the bubble wall is of the same order as the period for shape oscillations of the bubble; if the liquid pressure is zero, this period is of the order of (pR³lα)^{½} and is in the range 10⁻¹⁰ to 10⁻¹¹ s. Thus, the Franck-Condon principle applies, i.e., it should be considered that the transition of the electron occurs before the bubble has had time to change shape (see, for example, R. Schinke, Photodissociation Dynamics, (Cambridge, 1993)).

After optical excitation, the motion of the bubble can be calculated using the following steps. The bubble starts as a sphere of the same radius as the equilibrium 1s state. For this bubble size, the 1p wave function is found. The net pressure at each point on the bubble wall due to the combined effects of the electron, the surface tension, and the liquid pressure can then be determined. This pressure varies over the surface of the bubble, and so the bubble surface begins to move. This results in a velocity field in the liquid. To determine how the shape of the bubble evolves, it is necessary to calculate at each instant of time for the electron wave function, the force on the bubble wall, and how this force changes the motion of the liquid at the bubble. It should be a reasonable approximation to treat the liquid as an incompressible fluid. At low temperatures, e.g., at around 1.2 K or below, the effects of dissipation should be very small. This calculation requires substantial numerical computation, and I have not attempted to perform it.

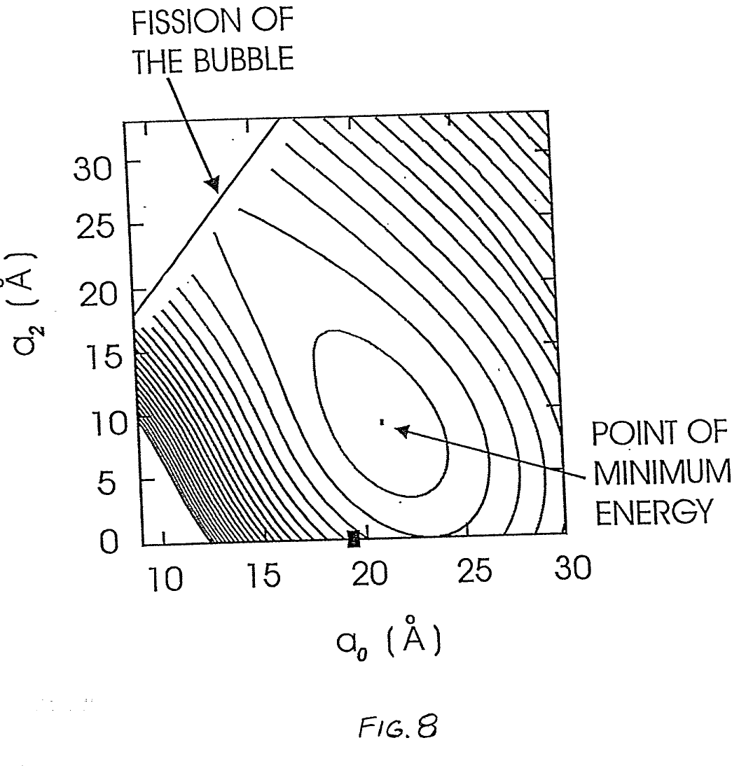

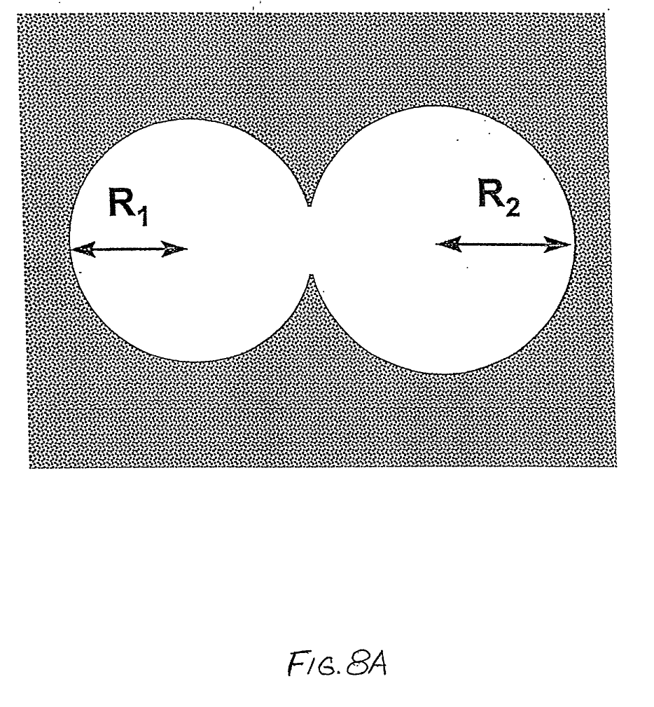

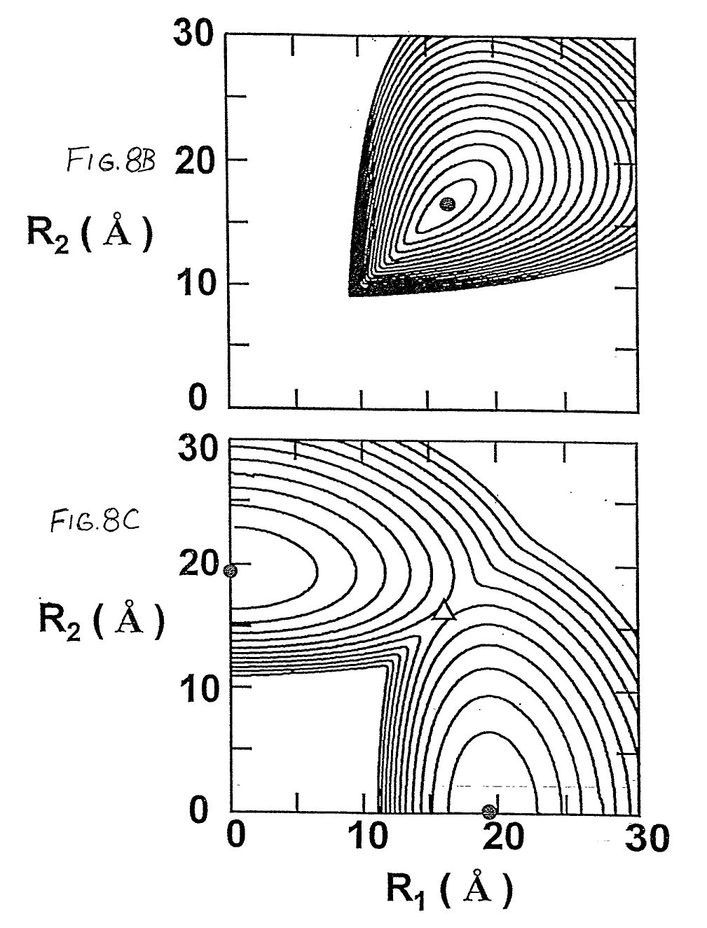

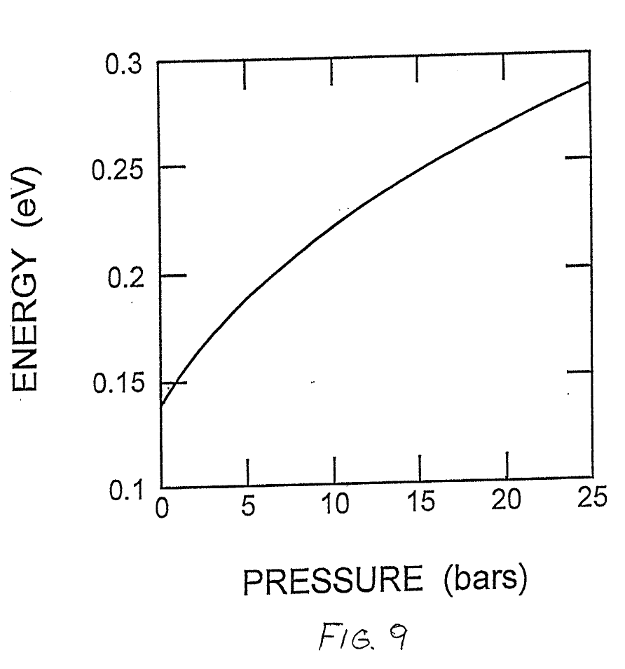

In the following, I have restricted attention to the examination of the potential energy surface in the configuration space of parameters defining the bubble shape. At the simplest non-trivial level, the shape of the bubble can be parameterized by just two coefficients a₀ and a₂ (see Eq. 8). The energy E from Eq. 3, which plays the role of the potential energy in the dynamical problem, can then be represented by a contour plot in the a₀₋ₐ₂ plane of FIG. 8.

FIG. 8 is contour plot of the energy of a bubble containing a 1p electron as a function of the parameters a₀ and a_{2.} The distance from the center of the bubble to the surface in the direction θ is a₀P₀ (cos θ)+a₂P₂ (cos θ). The contour closest to the energy minimum at 4.275×10⁻¹³ ergs corresponds to an energy of 4.4×10⁻¹³ ergs, and the energy difference between adjacent contours is 0.2×10⁻¹³ erg. Along the line on which a₂=2 a₀, the waist of the bubble has zero radius, and the bubble has split into two. The solid black square indicates the configuration of the bubble immediately after excitation to the 1p state. The starting configuration immediately after excitation from the 1s state to the 1p state corresponds to a₀=19.4, a₂=0 Å, and the energy is 4.828×10⁻¹⁴ ergs. Note that the bubble radius is increased to 19.4 Å (instead of 17.9 Å) because this figure has been calculated based on the simplified model in which the wave function is taken as zero at the bubble surface. The minimum energy is 4.275×10⁻¹⁴ ergs, and is at a₀^{min}=21.0 \acute{Å}, and a₂^{min}=8.8 \acute{Å}. The variation of the energy with a₀ and a₂ is important for the fission process. After excitation the bubble will move on some path in the a₀-a₂ plane.

Importantly, at sufficiently low temperature He II has negligible viscosity and thus the damping is small. Therefore, the bubble can explore the entire region of the a₀-a₂ plane in which the energy is less than its starting energy. FIG. 8 illustrates that this region extends out to the line on which a₂=2 a₀. On this line, the distance from the center of the bubble to the bubble surface is zero for θ=0, i.e., the waist of the bubble becomes zero and the bubble breaks into two parts. The calculation of the energy of the electron close to this line uses a large value for lₘₐₓ in Eq. 6. The lowest energy along the line on which fission occurs appears to be significantly below the starting energy of 4.828×10⁻¹⁴ ergs. Therefore, in He II (in the absence of damping) the bubble can reach this line and undergo fission.

As the pressure is increased, the equilibrium state of the bubble moves closer to the fission line (a₂=a₀) and the amount by which the starting energy of the bubble in the 1p state exceeds the energy at the fission line will increase.

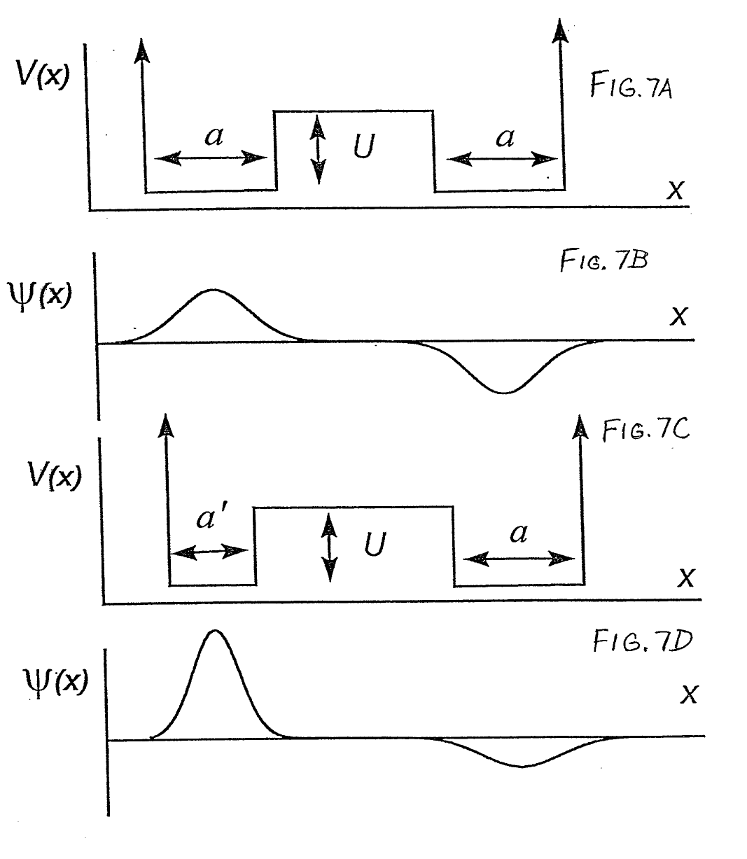

FIGS. 7A, 7B, 7C and 7D illustrate a highly-simplified model system including a particle that moves in one dimension in a potential consisting of two wells each of width a. As shows in FIG. 7A, the wells are separated by a barrier of height U. FIG. 7B illustrates a state in which the wave function has an equal amplitude in each well, but opposite sign. This state is analogous to the 1p state discussed above. I consider what happens when the wave function of an electron in the 1p state is close to being divided into two pieces. As described above, in the 1p state, there is a node in the region where the bubble waist will be pinched off.

Referring to FIG. 7C, in the model I changed the width of the right hand well to a′, where a′<a. The amplitude of the wave function increases in the smaller left hand well as shown in FIG. 7D, rather than flowing into the larger right hand well. Applying my model to an electron bubble and using Eq. 2, the inward pressure inside a bubble due to surface tension is given by Laplace's formula P=2α/R. Thus, the surface tension pressure is always larger in a smaller bubble. However, the wave function of the electron, and hence the outward pressure exerted by the electron, will be larger inside a smaller bubble. This tends to maintain equal radius for both bubbles just before fission. Therefore, importantly, the system has a natural stability that enables fission of the electron bubble.

Referring to FIG. 8A, I now consider a model of the final stage of the fission process. At this stage of the fission process, the original single bubble has been distorted into a volume consisting of two spheres of radius R₁ and R₂ that have a small overlap. The total energy of this system is as follows:

E=Eₑₗ+4πR₁²α+4πR₂²α, (10)

where Eₑₗ is the energy of the electron, and the correction to the surface area due to the small amount of overlap of the spheres has been neglected. For simplicity, I restrict attention to zero pressure. To calculate energy Eₑₗ, I write the wave function as follows:

ψ=c₁ψ₁+c₂ψ₂, (11)

where cₗ and c₂ are amplitudes, and I have used as basis states 1s wave functions ψ₁, and ψ₂ inside each of the two spheres. The energies of the basis states are:

$${E}_{1} = \frac{{h}^{2}}{8 {mR}_{1}^{2}} {E}_{2} = \frac{{h}^{2}}{8 {mR}_{2}^{2}} \qquad ( 12 )$$

Let the rate for quantum tunneling of the electron through the neck between the spheres be ┌. This will be a sensitive function of the degree of overlap of the spheres. The electron energy is given by

$${E}_{e1} = \frac{{E}_{1} + {E}_{2} \pm {[ {( {E}_{1} - {E}_{2} )}^{2} + 4 {ℏ}^{2} {Γ}^{2} ]}^{1 / 2}}{2} , \qquad ( 13 )$$

The + sign gives the energy of the excited state. This will be the energy that the 1p state will have after the bubble has reached the shape shown in FIG. 8A.

FIG. 8B is a contour plot of the total energy as a function of the radii R₁ and R₂ when the electron is in the excited state. The solid circle shows the configuration of minimum energy. The contour closest to the minimum corresponds to an energy of 4.8×10⁻¹³ ergs. This plot is for a fixed value of ┌ chosen to be 10¹³ sec⁻¹, which corresponds to [symbol] ┌=0.0066 eV. It can be seen from the figure that there is a single stable minimum with R₁=R₂=16.2 Å. A different choice for the value of ┌ changes the form of the contour lines in FIG. 8B, but the stable minimum with R₁=R₂ remains. Therefore, importantly, even when the bubble is close to splitting into two parts, the electron divides equally between the two spheres.

FIG. 8C is a contour plot of the total energy when the electron is in the ground state obtained by taking the negative sign in Eq. 13. The open triangle shows the location of a saddle point, and the two solid circles are minima. The saddle point is at R₁=R₂=16.2 Å, and the minima are at R₁=0, R₂=19.4 Å, and R₁=19.4 Å, R₂=0. The contours closest to the minima correspond to an energy of 3.4×10⁻¹³ erg. The energy difference between adjacent contours is 0.2×10⁻¹³ erg. Thus, as expected, when the electron is in its ground state, the lowest energy configuration is with the wave function confined in a single bubble.

As described above, the electrino bubbles are generated by fission of an electron bubble. I denote a bubble in which the integral of ¦ψ¦²=f by e^{f}. If the penetration of the wave function is neglected, the radius of a 1s e^{½} bubble at P=0 is smaller than the radius of an ordinary electron bubble by a factor of 2¼.

I now consider the wavelengths available for absorption by the electrino bubbles. The wave function inside one of the electrino bubbles is a 1s wave function normalized so that the integral of ψ², over the bubble is ½. apply an oscillating electric field to this bubble to find the frequencies at which absorption of energy takes place. Since the time-dependent Schrodinger equation is linear in ψ, these frequencies are unaffected by the normalization of the wave function. That is, optical absorption occurs at the same photon energies as for an ordinary electron bubble of the same radius.

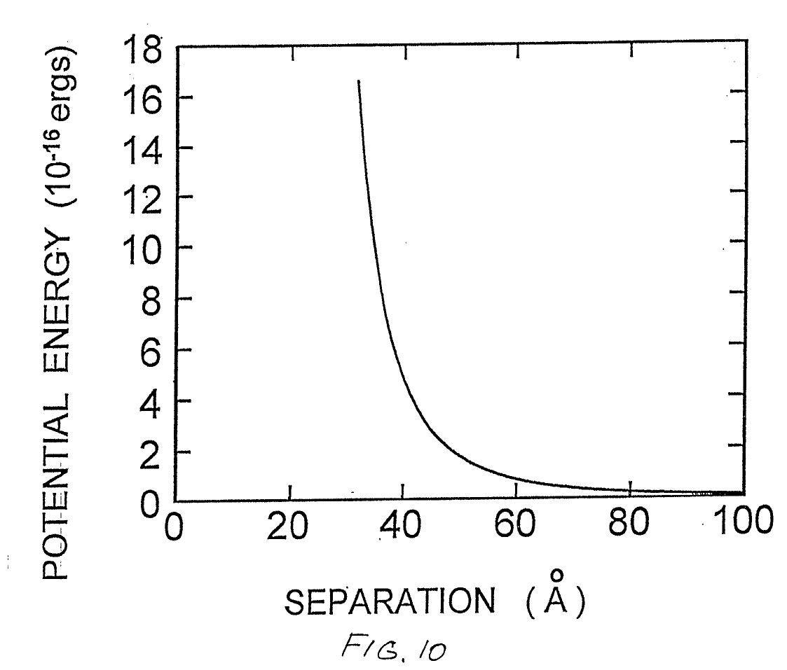

FIG. 9 shows the photon energy for the 1s→1p transition as a function of pressure. The results in FIG. 9 are based on the same model approximations that were used for FIG. 3, i.e., the surface tension was assumed to have the value 0.341 erg cm⁻² independent of pressure, the polarization energy was neglected, and the Wigner-Seitz approximation was used for the height V₀ of the energy barrier. Based on this model, the bubble radius for zero pressure is found to be 14.8 Å.

It may be possible to measure the effective mass of the bubble using microwaves, as has been done for normal bubbles (See J. Poitrenaud and F. I. B. Williams, Phys. Rev. Lett. 29, 1230 (1972) and 32, 1213 (E) (1974)). The mobility of a bubble at finite temperatures is proportional to the charge and varies inversely as the drag force F_{drag} on the bubble that arises from the interaction of the bubble with phonons and rotons. This drag force depends on the size of the bubble. To predict the results of these two experiments, it is necessary to know how to treat the charge on the bubble, i.e., does the bubble act as though it has charge ½e, or does it behave as though it has a full charge? It is not clear that quantum mechanics gives a definite answer to this question, and the answer may depend on the particular experiment.

For example, I consider an experiment to measure the mobility of e^{½} bubbles that uses a cell with travel distance w, and an applied electric field E. Suppose that an electron is injected from the cathode at one end of the cell of device 60 and is then optically excited so that two e^{½} bubbles are produced. The anode of the cell together with the electronics connected to it acts as a “measurement device” in the quantum mechanical sense. If the measurement device indicates that an electron has arrived, the work that has been done by the electric field must be as follows: e E w (E is the electric field, w is the distance across the cell ). This equals the total energy dissipated by the viscous drag force acting on the bubble (or bubbles) that have crossed the cell. The drag force F_{drag} acting on a bubble moving at small velocity equals γv, where γ is a coefficient that depends on the size of the bubble. In this experiment two e^{½} bubbles move through the liquid from the cathode to the anode, where the measurement device “finds” an electron in one of them. The dissipation is as follows: e E w=2γ_{½} vw, where γ_{½} is the drag coefficient for an e^{½} bubble. Thus, the mobility would be μ=v/E=e/2γ_{½.} Hence, the conclusion is that the mobility of the e^{½} bubble should be calculated using one half of the full charge of one electron together with the drag force on the bubble of a reduced size. However, this argument supposes that there is energy dissipation in the liquid along the path of the e^{½} bubble in which an electron is not found. If I take the viewpoint that this dissipation does not occur, I would instead be lead to the conclusion that the mobility should be μ=eγ_{½,} i.e., the e 1/² bubble acts as though it has the full charge.

I now consider the interaction between the electrino bubbles after the electron bubble in an excited state divides into two or more pieces. If the electron is inside one of the bubbles at position \vec{r} there will be an electric field \vec{E}(\vec{r},\vec{r}′)at the point \vec{r}′. Hence the energy associated with the polarization of He is as follows:

$$- \frac{1}{2} {α}_{He} \int {\vert \vec{E} ( \vec{r} , {\vec{r}}^{′} ) \vert}^{2} {ⅆ}^{3} {\vec{r}}^{′} , \qquad ( 14 )$$

where α_{He} is the polarizability of liquid helium per unit volume, and the integral is over the volume occupied by liquid. This result is correct to first order in α_{He}, and it has been assumed that the density of the liquid is unaffected by the electric field. The polarization energy as given by Eq. 14 is then averaged over all possible positions of the electron, giving the result

$${E}_{polzn} = - \frac{1}{2} {α}_{He} \int \int {\vert ψ ( \vec{r} ) \vert}^{2} {\vert \vec{E} ( \vec{r} , {\vec{r}}^{′} ) \vert}^{2} {ⅆ}^{3} \vec{r} {d}^{3} {\vec{r}}^{′} . \qquad ( 15 )$$

As the bubbles move further away from each other, there is a greater volume of helium in the region of strong electric field and hence the polarization energy decreases, i.e., becomes more negative. Thus, there is a weak repulsive interaction between the electrino bubbles. The potential as a function of the separation as calculated from Eq. 15 is shown in FIG. 10. Of course, one could also consider other contributions to the interaction energy coming from, for example, exchange of phonons or the long range van der Waals interaction between helium atoms.

I specifically described the generation of electrino bubbles by optical excitation and the 1s→1p transition. However, electrino bubbles may also be produced after other bound-bound transitions, such as the 1s→2p. Furthermore, electrino bubbles may also be produced after an electron is ejected from a bubble into an unbound state.

When the optical illumination contains a number of different wavelengths, electrino bubbles that have been produced as a result of a first fission process can undergo further division. Alternatively, electrino bubbles may be formed directly when an energetic electron enters helium and comes to rest. The combination of the above mechanisms provides electrino bubbles containing a substantial number of different fractions of an electron. The electrino bubbles are smaller than the original electron bubble. The mobility of a bubble in liquid helium depends on its size (see detailed discussion below). Thus, if the liquid is illuminated with light of the correct wavelength, the ionic mobility is modified (i.e., there is a photoconductivity effect). This modification of the mobility occurs for light wavelengths that excite the 1s→1p and 1s→2p transitions as shown in FIG. 6B. Electrino bubbles may also be produced by light of wavelength sufficiently short to excite the electron out of the bubble and into a free state.

The photoconductivity effect likely disappears above some temperature. As the temperature of superfluid helium increases the number of phonons and rotons in the liquid increases, and the viscosity increases. Thus, the motion of the wall of the bubble will be damped. Above a critical temperature T_{c}, the damping will become sufficiently large that fission does no longer occur (see previous discussion concerning FIG. 6).

It is difficult to perform a quantitative calculation of T_{c}, but I note the following points. The frequencies of the normal modes of a normal electron bubble were calculated by E. P. Gross and H. Tung-Li, Phys. Rev. Vol.170, 190 (1968). Using their results, it is straightforward to show that for helium above the lambda point, the l=0 and l=2 oscillations of a bubble are heavily damped, i.e. most of the vibrational energy is lost in less than half a cycle. This indicates that T_{c}, must have a value below T_{λ}. As the temperature is reduced below T_{λ}, the mean free path of rotons and phonons quickly becomes larger than the bubble diameter, and so it is no longer permissible to use the two-fluid model to calculate the damping of the bubble wall. The damping of the motion of the bubble wall could perhaps be calculated by using the measured mobility of negative ions in superfluid helium to estimate the drag on the bubble wall due to phonon-roton interactions. It would then be necessary to determine over what range of temperature this drag force is large enough to prevent fission.

An electron that is ejected from a bubble into helium will lose its kinetic energy very quickly, and will then form a new bubble. The time scale for this to happen should be of the same order of magnitude as the time scale for bubble shape oscillations, i.e., of the order of 10⁻¹⁰ to 10⁻¹¹ secs. Thus, I believe that the ejection of the electron from the bubble is not likely to decrease significantly the transit time of the electron across the experimental cell.

In superfluid helium, when a created electron bubble undergoes optical excitation the bubble splits into two smaller bubbles each containing a wave function ψ such that the integral of ¦ψ¦² over the volume of the bubble gives ½. The sum of the energy of the two e^{½} bubbles is less than the energy of the single bubble after optical excitation. Thus the two fissioned bubbles are stable since they are located in an energy minimum.

Device 60 can also create e^{½} bubbles by optical excitation of the 1p state of the normal negative ion, and then measure the mobility of the excited ion by a time-of-flight experiment. There is a second optical wavelength that causes a second fission and produces e^{¼} bubbles. The mobility of these could then be measured. Fission of bubbles after optical excitation between two bound states does not occur in any significant amount in liquid ⁴He above the lambda point or in the normal phase of ³He because the viscosity of the these liquids damps the motion of the bubble wall. I expect other physical situations in which fission occurs “naturally”, i.e., as a result of a spontaneous mechanism analogous to the process that takes place with a bubble in helium absorbs a photon, and that does not involve any external interaction other than the absorbed photon.

In the measurements that have been made of electrinos in superfluid helium, it has been found that the mobility of the electrinos is as much as a factor of five larger than the mobility of normal electrons. Both in superfluid helium and in a semiconductor, the mobility of charge carriers is determined by the interaction of the carrier with thermal excitations, these being phonons and rotons in helium and phonons in a semiconductor. Thus, it is reasonable to expect that in a semiconductor the mobility of electrinos may be significantly larger than the mobility of normal electrons. The interaction of the electrinos with light is also expected to be different from the interaction of normal electrons with light. Therefore, there are advantages in using electrino technology to improve the operation of semiconductor light-emitting devices, such as quantum well lasers.

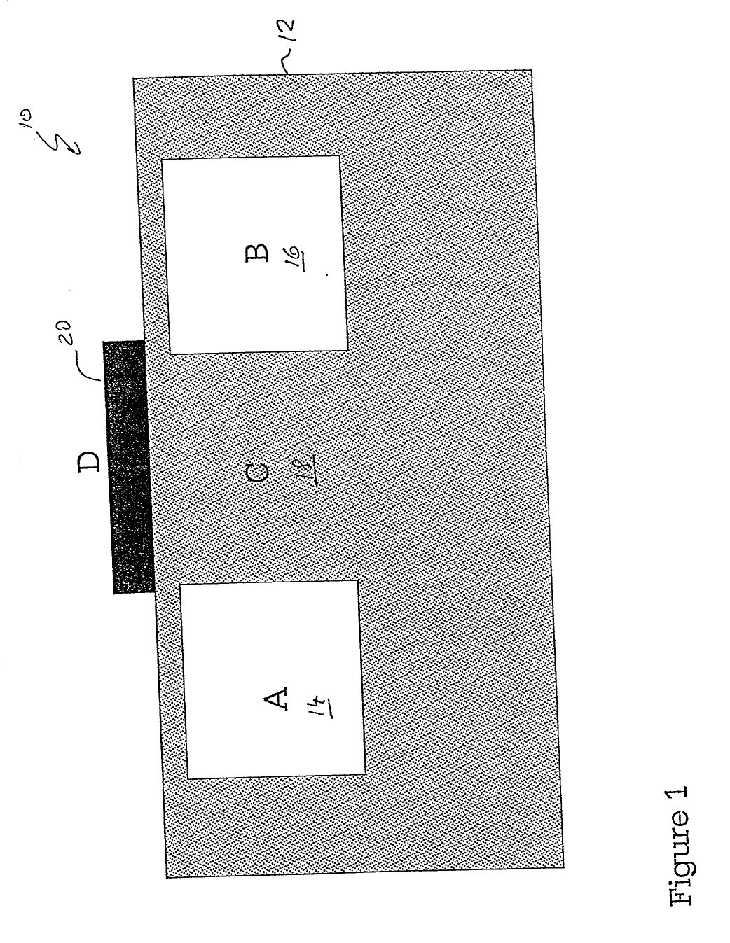

Having thus described the experimental regime performed with superfluid helium, reference is now made to FIG. 1 for showing schematically a device 10 for production of fractional particles used as carriers in electronic or optoelectronic devices. Device 10 includes a volume of material 12 (e.g., a solid, liquid or gas) with two energy regions 14 and 16, each having a known energy profile, separated by a barrier region 18. The shape and energy height of barrier region 18 is energy regulated by energy element 20. Energy element 20 provides electric field, magnetic field (electromagnetic energy), optical radiation, X-ray or gamma-ray radiation (or another radiation), thermal energy, or another energy for regulating properties of barrier region 18. (Alternatively, one or several energy elements are used to change the energy profile energy regions 14 and 16.)

Device 10 produces fractional particles (also called fractional carriers) by, for example, designing or altering two energy regions 14 and 16 (quantum wells) so that they have a selected energy profile (selected depths and sizes). The energy profile may be designed when material 12 is prepared or by applying external energy to material 12. A particle, located in any one of the two energy regions 14 and 16, has the wave function depending on the energy profile. For example, the particle wave function may be spread over energy regions 14 and 16 separated by a shallow energy barrier through which the particle can penetrate with relatively high probability.

Energy element 18 may include a gate, an electrode, a radiation port or antenna, a waveguide, an optical port or a similar element. Energy element 20 provides external energy for raising the barrier height of barrier 18 to make the amplitude for quantum tunneling through the barrier very small. (Alternatively, the energy in the two energy regions 14 and 16 may be lowered thus increasing the relative height of barrier region 18). After appropriately changing the relative energy of the two energy regions 14 and 16 and barrier region 18, a part of the wave function of the particle is trapped in the two energy regions 14 and 16. Thus, device 10 produces fractional particles confined in the two energy regions 14 and 16. The produced fractional particles (fractional carriers) are used in various electronic and optoelectronic devices.

FIG. 1A shows schematically another embodiment of a device for producing fractional particles. Device 30 includes a volume 32 filled with a solid, liquid or gas. Volume 32 includes two energy regions 34 and 36 each having a known energy profile separated by a barrier region 38. The energy of barrier region 38 is regulated by energy applied to this system using the above-described energy element. A particle located in any one of the two energy regions 34 and 36 has the wave function depending on the energy profile. The wave function of a particle can be controlled by the depths and geometry of the two energy regions 34 and 36, shown schematically by movable walls 35 and 37.

As was discussed above, when a wave packet of an elementary particle is incident on a potential barrier (i.e., barrier region 38), one part of the wave packet is transmitted, and another part is reflected. To determine the location of the particle, according to the conventional interpretation of quantum theory, the probability that the particle will be found on the right hand side of the barrier (i.e., in energy region 36) is as described by Eq. 1.

Let ψ_{L} and ψ_{R} be the lowest energy solutions of Schrodinger's equation for energy regions 34 and 36 of volume 32. An energy element provides external energy for raising the barrier height of barrier region 38 to make the amplitude for quantum tunneling through the barrier very small. When barrier region 38 is increased (the partition in FIG. 1A is moved to the closed position), the particle is confined in one energy region. The resulting energies corresponding to these solutions are E_{L} and E_{R}, respectively. The particle will exert the following pressure P on an end wall in the manner described by Eq. 2.

When barrier region 38 has low potential (low energy barrier shown as the open partition in FIG. 1A), the particle in the ground state spreads over energy regions 34 and 36 with equal probability. If the barrier height of barrier region 38 is rapidly increased, the system will not remain in the ground state, and the wave function of the electron will be nonzero in both energy regions 34 and 36 (i.e., the wave function will be nonzero in both the left and right regions). The rapid change in the barrier height traps a part of the wave function of the particle in each of the two energy regions 34 and 36. Thus, device 30 produces fractional particles (fractional carriers) confined within the two energy regions 34 and 36.

The fission process does not occur for certain energy profiles if the barrier energy of barrier 38 is increased very slowly. According to the adiabatic principle, in this case the particle remains in the ground state and the wave function changes as the barrier height increases. Thus, if ET_{L}<ET_{R} the wave function will be completely confined to the left hand part of the box, i.e., to the lower energy region. When barrier 38 is very high, the particle is confined to energy region 34, and the wave function in energy region 36 becomes zero. Thus, the particle can be detected in energy region 34 and consequently, in the right hand region, the wave function ψ_{R}=0, which means the probability P_{R}=0.

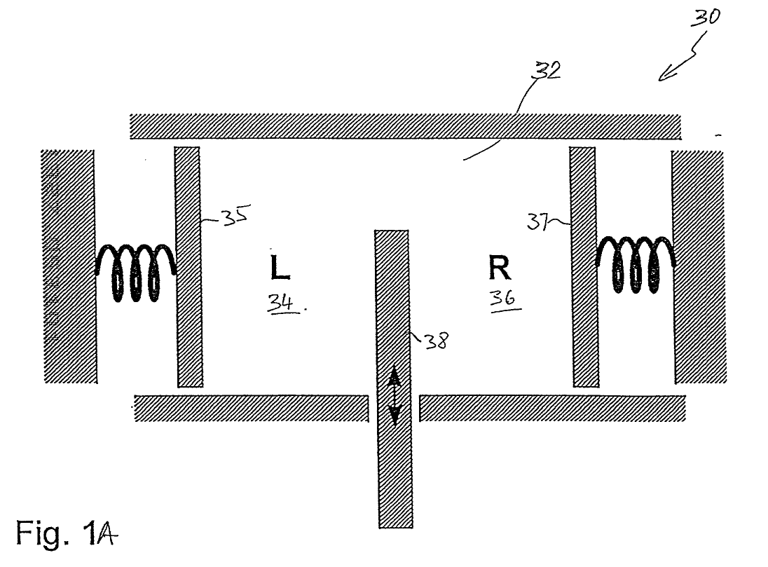

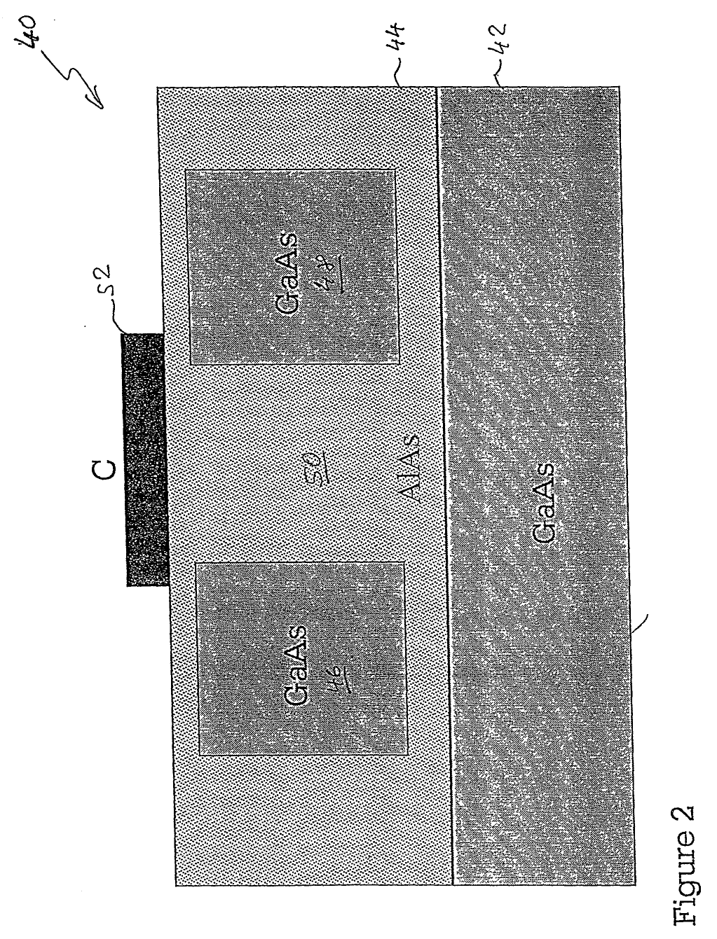

FIG. 2 shows schematically another embodiment of a device for producing fractional particles used as carriers in electronic or optoelectronic devices. A device 40 includes a generation unit and an active unit, both of which may be located on a semiconductor wafer, such as a gallium arsenide (GaAs) wafer 42. A layer 44 made of aluminum arsenide (AlAs) is deposited onto GaAs wafer 42 and includes two embedded GaAs regions 46 and 48. Each GaAs region 46 and 48 includes electrons (i.e., charge carriers). An electron can tunnel through an AlAs barrier 50 between the two GaAs regions 46 and 48. By applying a voltage to a gate electrode 52, AlAs barrier 50 is raised or lowered (i.e., the barrier potential is increased or decreased) which changes the tunneling amplitude for the electron. If the barrier 50 is raised rapidly (i.e., the barrier potential is increased rapidly), a part of the wave function is trapped in each of the two GaAs regions 46 and 48. Specifically, if barrier 50 is raised in a time that is less than the time for a confined electron to tunnel through barrier 50, fractions f₁, and f₂, associated with the electron wave functions, are created and the electron is divided into two “electrinos.” That is, a charge carrier is fissioned into two fractional carriers. One electrino is produced in each of the two quantum well regions 46 and 48. The fractions f₁, and f₂ depend on the geometry of the quantum well regions 46 and 48, and the rate at which the potential barrier is raised. The two electrinos (i.e., fractional carriers) are used in various electronic and optoelectronic devices.

The depths and geometry of GaAs regions 46 and 48 (i.e., two quantum wells) and the width and height of barrier 50 are selected in a way that, before barrier 50 is raised, the wave function of the electron has an appreciable amplitude in both GaAs regions 46 and 48. This condition can be satisfied, for example, by making GaAs regions 46 and 48 identical, but this is not a necessary condition for an electron to fission into two electrinos (wherein each electrino is located in one GaAs regions 46 and 48). Device 40 may optionally include several quantum well regions.

The dimensions of the semiconductor embodiment of these teachings may be as those lying within the normal range for nanostructures that can currently be constructed (i.e., dimensions between 1 nm and 10,000 nm.) The controlling waveform is switched sufficiently fast for the wave function to be trapped on each side. How fast this is depends on how small the regions, such as 14 and 16, are, and how close they are to having the same size. If the dimensions (size and shape) of the regions 14 and 16 are identical (which is impossible to achieve in practice), the potential of the gate 20 could be changed at an arbitrarily slow rate and the wave function would still divide into two equal parts. On the other hand, if A is a cube of side 100 nm and B is a cube of side 200 nm, the potential of the gate 20 is raised within a time of the order of 10⁻¹¹ secs in order for a significant fraction of the wave function to be trapped on each side.

In order for some part of the wave function to be trapped in each of the regions on either side of the barrier it is necessary for the barrier to move at a rate such that the wave function of the particle does not deform adiabatically. The required rate is dependent on the size and shape of the regions. As was noted, if the two regions on opposite sides of the barrier are of identical size and shape, the energies E_{L} and E_{R} will be equal. In this case the wave function will have an equal magnitude in the two regions, regardless of the time interval over which the partition is closed. The larger the difference between E_{L} and E_{R} the faster it is necessary to close the partition in order for an appreciable division of the wave function to result. If the size of the regions differs substantially, then the difference between E_{L} and E_{R} will be large. For example, it might happen that E_{L}=2 E_{R}. In this case, it would be required to move the partition within a time interval which is of the order of [symbol] /E_{L} or less, where [symbol] is Planck's constant.

While described in the context of providing quantum wells in the semiconductor material, it should be appreciated that quantum wires and/or quantum dots could be provided as well.

Preferred embodiments of these teachings include one or more of the following features. The particles may be electrons. The energy element may include an internal or an external energy source. The energy element may include a gate, an electrode, a grid, an optical port, a radiation antenna, a magnet, a heating element, or another element. The energy element may provide one or more of the following: an electric field, a magnetic field, optical radiation, ionizing radiation, thermal energy, or the injection of particles or ions.

The active unit of the electronic or optoelectronic device may facilitate interaction of the fractional carriers with photons, phonons, rotons, electrons, holes, Cooper pairs, ions, atoms, or their combination.

The active unit may include a detector and the functional output then corresponds to a detected signal. The detector provides the detected signal reflecting electromagnetic radiation received at the detector. Alternatively, the active unit may include a switch and the functional output corresponds to a selected state, or the active unit includes an amplifier and the functional output provides amplified input signal. Alternatively, the active unit may include a filter and the functional output corresponds to a modified input signal, or the active unit may include a phase shifter or splitter.

It should further be appreciated that these teachings provide a mechanism to encode, store and retrieve information. For example, the presence or absence of a portion of a wave function or a fraction of a particle within a particular storage structure or region (e.g., a quantum well, a quantum wire or a quantum dot) may be indicative of a presence or absence of a bit of information. Furthermore, by controlling an amount of the fractional particle within a given region, a multi-level coding scheme may be realized. For example, by controlling the wave function so as to trap none, one quarter, one half, three quarters or all of the wave function within a region, a five level information encoding and storage scheme can be implemented. As was discussed above, control of the wave function trapping may be achieved by controlling the rate of change of the gate potential, and readout of the stored information may be achieved by an electrical or by an optical process.

Having thus described these teachings and various illustrative embodiments and uses as well as some of its advantages and optional features, it will be apparent that such embodiments are presented by way of example only and not by way of limitation. Those persons skilled in the art will readily devise further modifications developments and enhancements to and improvements on these embodiments, such as variations on the disclosed methods and systems, as well as additional embodiments, without departing from the spirit and scope of the invention. It is impossible to enumerate all of the variations that will quite quickly occur to those in the art. Accordingly, the invention is limited only as defined in the following claims and equivalents thereto.

What is claimed is:

1. A method of generating fractional particles, comprising:
providing a volume of a material including a region having a selected energy distribution;
providing a particle and arranging the particle in said region of said selected energy distribution; and
supplying energy to said region to create fractional particles from said particle.

2. The method of claim 1, wherein said providing a volume of a material includes providing a semiconductor material.

3. The method of claim 2, wherein said material includes a quantum well.

4. The method of claim 2, wherein said region of said selected energy distribution includes a quantum wire.

5. The method of claim 2, wherein said region of said selected energy distribution includes a quantum dot.

6. The method of claim 27 wherein said providing a particle includes providing an electron.

7. The method of claim 2, wherein said process of supplying energy includes supplying external energy to said semiconductor material.

8. The method of claim 2, wherein said process of supplying external energy includes applying a voltage at a gate.

9. The method of claim 2, wherein said process of supplying external energy includes applying external energy to increase a barrier between two quantum wells.

10. The method of claim 1, wherein said process of providing a volume of a material includes providing liquid helium in a superfluid state.

11. The method of claim 10, wherein said liquid helium is ⁴He.

12. The method of claim 10, wherein said liquid helium is ³He.

13. The method of claim 10, wherein said providing a particle includes providing an electron.

14. The method of claim 10, wherein said supplying energy includes supplying external energy to said liquid helium.

15. The method of claim 13, wherein said process of supplying external energy includes exciting said particle by photons.

16. The method of claim 14, wherein said particle is an electron.

17. The method of claim 10, wherein said supplying energy and providing said particle includes injecting energized electrons into said liquid helium.

18. In an electronic or optoelectronic device, a method comprising processes including providing a region of a selected energy distribution in a selected material including a particle, arranging said particle in said region of said selected energy distribution, supplying energy to said region to create fractional carriers from said particle; and using said created fractional carriers in said device.

19. The method of claim 18, wherein said process of supplying energy includes applying a voltage at a gate.

20. The method of claim 18, wherein said process of supplying energy includes emitting light into said region.

21. The method of claim 18, wherein said process of supplying energy includes injecting particles into said region.

22. The method of claim 18, wherein said process of supplying energy includes introducing electromagnetic or other radiation into said region.

23. An electronic or optoelectronic device, comprising:
a generation unit including an energy source and a material having a region of a selected energy distribution including a particle arranged in said region of said selected energy distribution, said energy element being constructed and arranged to provide energy to said region to create fractional carriers from said particle; and
an active unit arranged to receive said created fractional carriers and manipulate said fractional carriers to provide a functional output.

24. The electronic or optoelectronic device of claim 23, wherein said active unit facilitates interaction of said fractional carriers with one of the following: photons, phonons, rotons, electrons, holes, Cooper pairs, ions, or atoms.

25. The electronic or optoelectronic device of claim 23, wherein said active unit includes a detector and said functional output corresponds to a detected signal.

26. The electronic or optoelectronic device of claim 25, wherein said detector provides said detected signal that is indicative of electromagnetic radiation received at said detector.

27. The electronic or optoelectronic device of claim 23, wherein said active unit includes a switch and said functional output corresponds to a selected state.

28. The electronic or optoelectronic device of claim 23, wherein said active unit includes an amplifier and said functional output provides amplified input signal.

29. The electronic or optoelectronic device of claim 23, wherein said active unit includes a filter and said functional output corresponds to a modified input signal.

30. The electronic or optoelectronic device of claim 23, wherein said active unit includes a phase shifter.

31. A method for storing information, comprising:
encoding information; and
storing the encoded information by trapping a portion of a wave function within a spatial region.

32. The method of claim 31, wherein said spatial region is located within semiconductor material.

33. The method of claim 32, wherein said spatial region comprises at least one of a quantum well, a quantum wire or a quantum dot.

34. The method of claim 32, wherein the process of storing the encoded information includes changing a voltage potential within the semiconductor material at a minimum predetermined rate.
